(19) United States
(12) Patent Application Publication
(10) Pub. No.: US 2026/0362982 A1
(43) Pub. Date: Nov. 12, 2026

(54) Method for Manufacturing Magnetic Memory Cell

(71) Applicant: ZHEJIANG HIKSTOR TECHNOLOGY CO., LTD., Hangzhou, Zhejiang (CN)

(72) Inventors: Lijie SHEN, Hangzhou, Zhejiang (CN); Zhimeng YU, Hangzhou, Zhejiang (CN); Jianqiang ZHENG, Hangzhou,Zhejiang (CN)

(21) Appl. No.: 19/141,312

(22) PCT Filed: Nov. 28, 2023
(86) PCT No.: PCT/CN2023/134816

§ 371 Date: Jun. 19, 2025

(30) Foreign Application Priority Data
Dec. 26, 2022 (CN) 202211700769.5

(51) Int. Cl. H10N 50/01; H10B 61/00; H10N 50/10

(52) U.S. Cl. CPC H10N 50/01; H10B 61/10; H10N 50/10

(57) ABSTRACT

The present disclosure provides a method for manufacturing a magnetic memory cell, including: providing a substrate, and a bottom interconnection structure and an MTJ bottom electrode located on a bottom interconnection structure are formed on the substrate; forming a magnetic tunnel junction on the MTJ bottom electrode, and a metal hard mask is reserved on a top of the magnetic tunnel junction; depositing a protective layer and an interlayer dielectric; performing a planarization treatment on the interlayer dielectric; etching back the interlayer dielectric and the protective layer, so as to exposes a surface and a part of side walls of the metal hard mask; forming a top electrode metal layer on the metal hard mask; and etching a top electrode metal layer, and the interlayer dielectric and the protective layer below the top electrode metal layer, so as to form an MTJ top electrode.

### CROSS-REFERENCE TO RELATED APPLICATION

The present disclosure claims the priority of Chinese Patent Application 202211700769.5, filed in the China National Intellectual Property Administration on Dec. 26, 2022, and entitled “Method for Manufacturing Magnetic Memory Cell”, the entire contents of which are herein incorporated by reference.

### TECHNICAL FIELD

The present disclosure relates to the technical field of semiconductor devices, and in particular to a method for manufacturing a magnetic memory cell.

### BACKGROUND

In recent years, a magnetic random access memory (MRAM) employing the magnetoresistive effect of a magnetic tunnel junction (MTJ) is considered to be a future solid-state non-volatile memory, which has the characteristics of high-speed read-write, large capacity and low energy consumption. As a core component of the MRAM, a basic structure of an MTJ cell includes a bottom electrode, an MTJ stack, and a top electrode.

During the process of forming an interconnection between an existing MTJ cell and an MTJ top electrode, a metal hard mask on the top of the MTJ is often exposed by a chemical mechanical polishing (CMP) method, and then a metal of the MTJ top electrode is deposited. However, with the continuous reduction in the size of the MTJ cell, a CMP planarization process requires a very high removal selection ratio between the metal hard mask on the top of the MTJ cell and a dielectric to be planarized and ensures better uniformity. This proposes a very high process requirement for the CMP process, and thus it is very difficult to implement.

### SUMMARY

In view of this, the present disclosure provides a method for manufacturing a magnetic memory cell.

The present disclosure provides a method for manufacturing a magnetic memory cell, including:
a substrate is formed, and a bottom interconnection structure and an MTJ bottom electrode located on a bottom interconnection structure are formed on the substrate;
a magnetic tunnel junction is formed on the MTJ bottom electrode, and a metal hard mask is reserved on a top of the magnetic tunnel junction;
a protective layer and a first interlayer dielectric are deposited;
a planarization treatment is performed on the first interlayer dielectric;
the first interlayer dielectric and the protective layer are etched back, so as to exposes a surface and a part of side walls of the metal hard mask;
a top electrode metal layer is formed on the metal hard mask; and
a top electrode pattern is photoetched, and the top electrode metal layer, and the first interlayer dielectric and the protective layer below the top electrode metal layer are etched according to the top electrode pattern, so as to form an MTJ top electrode.

Optionally, the planarization treatment is performed on the first interlayer dielectric includes:
a preceding thickness value of the first interlayer dielectric is measured before polishing, then a polishing duration is determined according to requirements of a polishing rate and a post thickness value, and regular polishing is performed on the first interlayer dielectric.

Optionally, after the metal hard mask is exposed, and before the top electrode metal layer is formed, the method further includes: in-situ plasma cleaning, dry-method photoresist removal and wet-method cleaning processes are performed on the metal hard mask, so as to remove a polymer or a metal oxide on the surface of the metal hard mask.

Optionally, the metal hard mask is a single-layer structure formed by one of or a combination of multiple layers of tantalum (Ta), tantalum nitride (TaN), titanium (Ti), titanium nitride (TiN), tungsten (W), and ruthenium (Ru).

Optionally, a material of the MTJ top electrode is one or a combination of more of tantalum, tantalum nitride, titanium, and titanium nitride.

Optionally, a material of the protective layer is ethyl polysilicate (TEOS).

Optionally, a material of the first interlayer dielectric is silicon oxide (SiO₂), silicon nitride (Si₃N₄), or silicon oxynitride (SiON).

Optionally, a feature size of the MTJ top electrode is greater than a feature size of the MTJ bottom electrode.

Optionally, after the MTJ top electrode is formed, the method further includes: a top interconnection structure is formed.

### BRIEF DESCRIPTION OF THE DRAWINGS

FIG. 1 is a schematic flowchart of a method for manufacturing a Magnetic Memory Cell provided in an embodiment of the present disclosure; and FIG. 2 to FIG. 9 are schematic diagrams of sectional structures corresponding to steps of a method for manufacturing a Magnetic Memory Cell provided in an embodiment of the present disclosure.

### DETAILED DESCRIPTION OF THE EMBODIMENTS

In order to make the objectives, technical solutions and advantages of the embodiments of the present disclosure clearer, the technical solutions in the embodiments of the present disclosure will be clearly and completely described below in combination with the drawings in the embodiments of the present disclosure, but it should be understood that these descriptions are merely exemplary and are not intended to limit the scope of the present disclosure. All of other embodiments, obtained by those ordinary skilled in the art based on the embodiments of the present disclosure without creative efforts, shall fall within the protection scope of the present disclosure. In addition, in the following description, descriptions of well-known structures and technologies are omitted to avoid unnecessarily obscuring the concepts of the present disclosure.

Various schematic structural diagrams according to the embodiments of the present disclosure are shown in the drawings. These figures are not drawn to scale, and some details are exaggerated for the purpose of clear expression, and some details may be omitted. The shapes of various regions and layers, and relative sizes and positional relationships therebetween shown in the figures are merely exemplary, there may be deviations due to manufacturing tolerances or technical limitations in practice, and those skilled in the art may additionally design regions/layers with different shapes, sizes and relative positions according to actual needs.

In the context of the present disclosure, when one layer/element is referred to as being “on” another layer/element, the layer/element may be directly located on the other layer/element, or there may be intervening layers/elements therebetween. In addition, if one layer/element is located “on” another layer/element in one orientation, the layer/element may be located “below” the other layer/element when the orientation is turned.

Some implementations of the present disclosure will be described in detail below in combination with the drawings. In the case of no conflict, the following embodiments and features in the embodiments may be combined with each other.

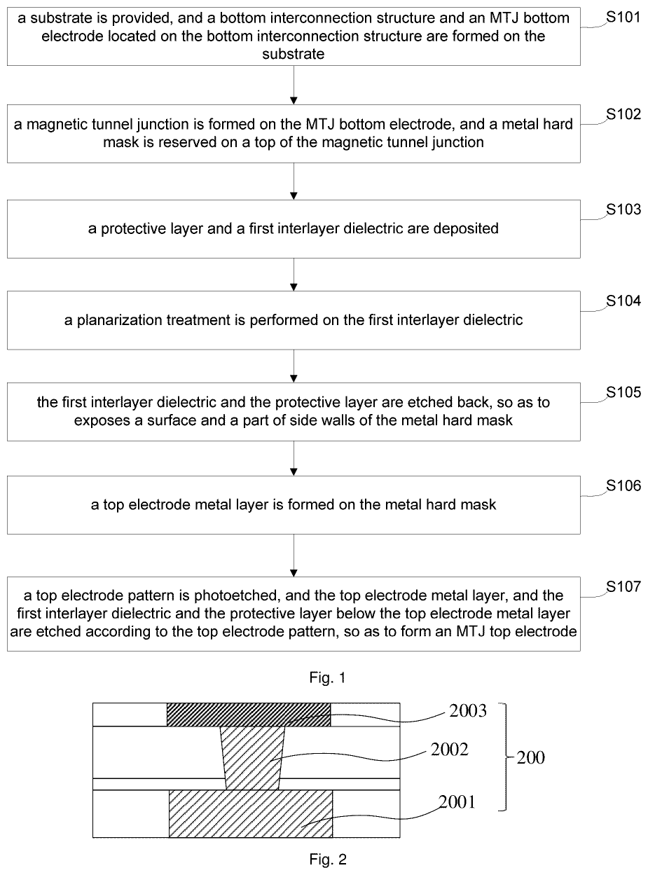

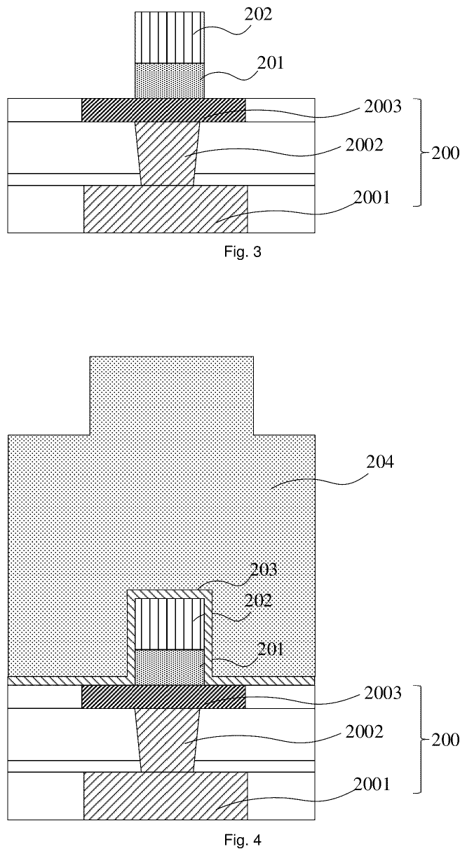

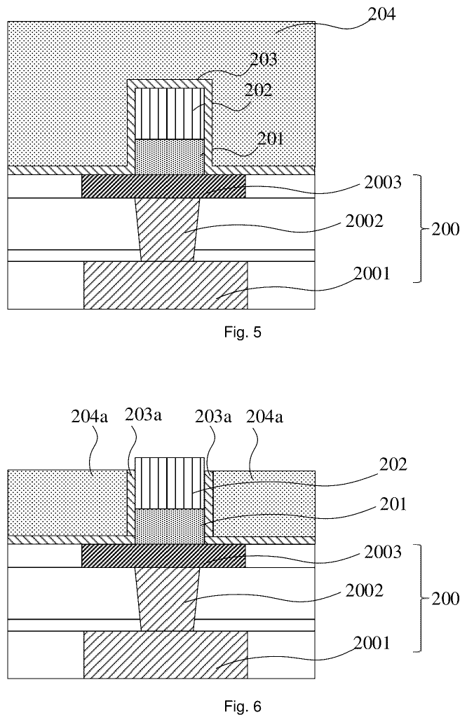

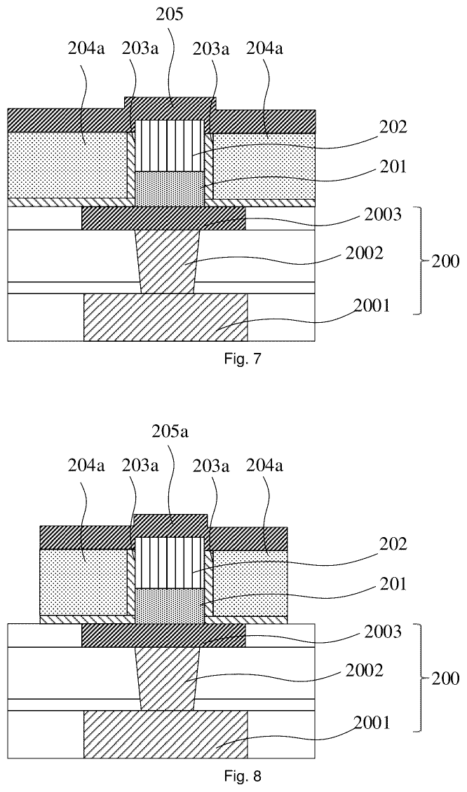

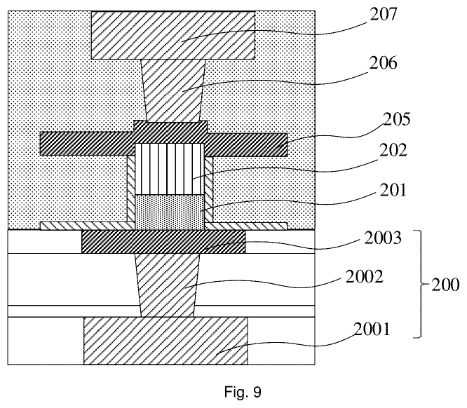

An embodiment of the present disclosure provides a method for manufacturing a magnetic memory cell, so as to improve the manufacturing process of an MTJ top electrode, reduce the process difficulty, and improve a process window, as shown in FIG. 1, including the following steps:

S101, a substrate is provided, and a bottom interconnection structure and an MTJ bottom electrode located on the bottom interconnection structure are formed on the substrate;

S102, a magnetic tunnel junction is formed on the MTJ bottom electrode, and a metal hard mask is reserved on a top of the magnetic tunnel junction;

S103, a protective layer and a first interlayer dielectric are deposited;

S104, a planarization treatment is performed on the first interlayer dielectric;

S105, the first interlayer dielectric and the protective layer are etched back, so as to exposes a surface and a part of side walls of the metal hard mask;

S106, a top electrode metal layer is formed on the metal hard mask; and

S107, a top electrode pattern is photoetched, and the top electrode metal layer, and the first interlayer dielectric and the protective layer below the top electrode metal layer are etched according to the top electrode pattern, so as to form an MTJ top electrode.

FIG. 2 to FIG. 8 illustrate cross-sectional structural diagrams of some stages of the method for manufacturing the magnetic memory cell provided in the embodiment of the present disclosure. The steps are discussed in detail below.

In step S101, as shown in FIG. 2, a substrate 200 is provided, a bottom interconnection structure is formed on the substrate 200, in the present embodiment, the substrate 200 may include a semiconductor material, for example, silicon, germanium, and silicon germanium, and various types of circuit patterns, for example, transistors, lower-layer metal wires 2001, and the like, are formed on a silicon substrate in advance. Then, an etching stop layer is formed as a stop layer of an etching process when a bottom via 2002 is subsequently formed, and the etching stop layer is generally made from silicon nitride (SiN). The bottom interconnection structure includes a bottom metal layer 2001 and the bottom via 2002, and an MTJ bottom electrode 2003 is disposed on the bottom interconnection structure. The thickness of the bottom electrode 2003 may be 10-40 nm. The bottom electrode 2003 may include tantalum nitride, tantalum, titanium nitride, titanium, and the like. A second interlayer dielectric surrounds the bottom interconnection structure and the MTJ bottom electrode.

In step S102, as shown in FIG. 3, a magnetic tunnel junction 201 is formed on the MTJ bottom electrode 2003, and a metal hard mask 202 is reserved on the top of the magnetic tunnel junction 201. The implementation method of the step generally includes: a multi-layer thin film and the metal hard mask of the magnetic tunnel junction are sequentially deposited, then patterning is first performed on the metal hard mask, the metal hard mask is then used as an etching mask, and the multi-layer thin film of the magnetic tunnel junction is etched by, for example, an ion beam etching (IBE) process, so as to obtain the magnetic tunnel junction. The magnetic tunnel junction 201 is of a stacked structure at least including a free layer, a barrier layer and a reference layer. The metal hard mask 202 may be of a single-layer structure, and the material thereof may be selected from one of tantalum (Ta), tantalum nitride (TaN), titanium (Ti), titanium nitride (TiN), tungsten (W), and ruthenium (Ru). The metal hard mask 202 may also be of a multi-layer structure, and the material of each layer may be selected from one of tantalum (Ta), tantalum nitride (TaN), titanium (Ti), titanium nitride (TiN), tungsten (W) and ruthenium (Ru), and the materials of a plurality of layers are combined. The thickness of the metal hard mask 202 may be 30-60 nm.

In step S103, as shown in FIG. 4, a protection layer 203 and a first interlayer dielectric 204 are deposited. The protection layer 203 conformally covers the surfaces of the magnetic tunnel junction 201 and the metal hard mask 202. The protective layer 203 is used for protecting the magnetic tunnel junction 201 from oxidation. The protective layer 203 may include silicon oxide or a low-k dielectric material with a dielectric constant less than that of silicon oxide (that is, less than about 3.9), for example, ethyl polysilicate (TEOS). The first interlayer dielectric 204 is used for filling gaps between adjacent cylindrical magnetic tunnel junctions. In the present embodiment, the first interlayer dielectric 204 and the protective layer 203 are made from different materials. For example, the material of the first interlayer dielectric 204 may be silicon oxide (SiO₂), silicon nitride (Si₃N₄), or silicon oxynitride (SiON). The protective layer 203 and the first interlayer dielectric 204 are preferentially deposited by plasma enhanced chemical vapor deposition (PECVD), physical vapor deposition (PVD), or an electron beam evaporation process.

In step S104, as shown in FIG. 5, a planarization treatment is performed on the first interlayer dielectric 204. In the step, it is only necessary to planish the first interlayer dielectric, it is not necessary to grind the first interlayer dielectric to the metal hard mask, and the top of the metal hard mask is subsequently opened by etching the top of the MTJ.

In step S105, as shown in FIG. 6, the first interlayer dielectric 204 and the protective layer 203 are etched back, so that the metal hard mask 202 exposes surfaces and part of side walls thereof. The surface of a first interlayer dielectric 204a remained after etching and a protective layer 203a remained after etching is lower than the surface of the metal hard mask 202. Preferably, the metal hard mask 202 may have a convex spherical contact surface, thereby increasing a contact area with the MTJ top electrode.

The etching in this step is performed according to an etching selection ratio of the first interlayer dielectric 204, the protective layer 203 and the metal hard mask 202, depending on the content of an etching menu, the top of the metal hard mask protrudes after etching, and the top and the MTJ protection layer and the first interlayer dielectric near the top are etched away. A condition with a lower etching rate and a higher selection ratio is preferably used, so that process windows may be increased, and the hard mask (HM) loss may be reduced.

It should be noted here that, after the first interlayer dielectric 204 and the protective layer 203 are etched back, the first interlayer dielectric and the protective layer between adjacent storage units are not etched away.

In addition, it should be noted that, in order to enable the metal hard mask 202 to have the convex spherical contact surface, after etching, the method further includes: in-situ plasma cleaning, dry-method photoresist removal, wet-method cleaning and other processes are performed on the metal hard mask 202 to remove a polymer or a metal oxide on the surface of the metal hard mask, so as to obtain a lower contact resistance. CHF₃ or CF₄ is preferably used as a dry etching gas.

In step S106, as shown in FIG. 7, a top electrode metal layer 205 is formed on the metal hard mask 202. The material of the top electrode metal layer 205 may be one or a combination of more of tantalum, tantalum nitride, titanium, and titanium nitride. The top electrode metal layer 205 is preferably formed by metal physical vapor deposition.

In step S107, as shown in FIG. 8, a top electrode pattern is photoetched, the top electrode metal layer 205, and the first interlayer dielectric 204a and the protective layer 203a below the top electrode metal layer 205 are etched according to the top electrode pattern, so as to form an MTJ top electrode 205a. A feature size of the top electrode 205a depends on a used photomask, and in the present embodiment, the feature size of the MTJ top electrode 205a is greater than a feature size of the MTJ bottom electrode 2003.

Further, after the MTJ top electrode 205a is formed, as shown in FIG. 9, the method further includes: a top interconnection structure is formed. In the present embodiment, the top interconnect structure includes a top via 206 and a top metal layer 207. The step may be implemented by conventional processes, for example, a dual damascene process.

According to the method for manufacturing the magnetic memory cell provided in the embodiment of the present disclosure, when the MTJ top electrode is formed, the first interlayer dielectric is first planished by a CMP process without the need to expose the metal hard mask, and then the metal hard mask on the top of the MTJ is subsequently opened by an etching process, thereby reducing the complexity of the CMP process, and improving the circulation speed of the product. Moreover, the top of the MTJ is etched under the condition of a lower etching rate and a higher selection ratio, so that process windows may be increased, and the loss of the metal hard In the above description, technical details such as composition and etching of each layer are not described in detail. However, it should be understood by those skilled in the art that, layers, regions, and the like of a desired shape may be formed by various technical means. In addition, in order to form the same structure, those skilled in the art may also design a method that is not exactly the same as the method described above. In addition, although various embodiments are described above respectively, this does not mean that the measures in the various embodiments may not be advantageously combined for use.

The above descriptions are only specific implementations of the present disclosure, but the protection scope of the present disclosure is not limited thereto, and any changes or substitutions that may be easily conceived of by those skilled in the art within the technical scope disclosed in the present disclosure shall fall within the protection scope of the present disclosure. Therefore, the protection scope of the present disclosure shall be subject to the protection scope of the claims.

What is claimed is:

1. A method for manufacturing a magnetic memory cell, comprising:
providing a substrate, wherein a bottom interconnection structure and a magnetic tunnel junction (MTJ) bottom electrode located on a bottom interconnection structure are formed on the substrate;
forming a magnetic tunnel junction on the MTJ bottom electrode, wherein a metal hard mask is reserved on a top of the magnetic tunnel junction;
depositing a protective layer and a first interlayer dielectric;
performing a planarization treatment on the first interlayer dielectric;
etching back the first interlayer dielectric and the protective layer, so as to exposes a surface and a part of side walls of the metal hard mask;
forming a top electrode metal layer on the metal hard mask; and
photoetching a top electrode pattern, and etching the top electrode metal layer, and the first interlayer dielectric and the protective layer below the top electrode metal layer according to the top electrode pattern, so as to form an MTJ top electrode.

2. The method according to claim 1, wherein performing the planarization treatment on the first interlayer dielectric comprises:
measuring a preceding thickness value of the first interlayer dielectric before polishing, then determining a polishing duration according to requirements of a polishing rate and a post thickness value, and performing regular polishing on the first interlayer dielectric.

W

3. The method according to claim 1, wherein after the metal hard mask is exposed, and before the top electrode metal layer is formed, the method further comprises: performing in-situ plasma cleaning, dry-method photoresist removal and wet-method cleaning processes on the metal hard mask, so as to remove a polymer or a metal oxide on the surface of the metal hard mask.

4. The method according to claim 1, wherein the metal hard mask is a single-layer structure formed by one of or a combination of multiple layers of tantalum (Ta), tantalum nitride (TaN), titanium (Ti), titanium nitride (TiN), tungsten (W), and ruthenium (Ru).

5. The method according to claim 1, wherein a material of the MTJ top electrode is one or a combination of more of tantalum, tantalum nitride, titanium, and titanium nitride.

6. The method according to claim 1, wherein a material of the protective layer is ethyl polysilicate (TEOS).

7. The method according to claim 1, wherein a material of the first interlayer dielectric is silicon oxide (SiO₂), silicon nitride (Si₃N₄), or silicon oxynitride (SiON).

8. The method according to claim 1, wherein a feature size of the MTJ top electrode is greater than a feature size of the MTJ bottom electrode.

9. The method according to claim 1, wherein after the MTJ top electrode is formed, the method further comprises: forming a top interconnection structure.

10. The method according to claim 1, wherein depositing the protective layer and the first interlayer dielectric comprises:
depositing the protective layer by plasma enhanced chemical vapor deposition, physical vapor deposition or an electron beam evaporation process, so that the protective layer conformally covers surfaces of the magnetic tunnel junction and the metal hard mask; and
forming the first interlayer dielectric on an exposed surface of the protective layer by the plasma enhanced chemical vapor deposition, the physical vapor deposition or the electron beam evaporation process.

11. The method according to claim 9, wherein forming the top interconnection structure comprises:
sequentially forming a top via and a top metal layer on the MTJ top electrode via a dual damascene process, so as to obtain the top interconnection structure comprising the top via and the top metal layer.

12. The method according to claim 1, wherein forming the top electrode metal layer on the metal hard mask comprises:
forming the top electrode metal layer on the metal hard mask by metal physical vapor deposition.

13. The method according to claim 1, wherein forming the magnetic tunnel junction on the MTJ bottom electrode comprises:
sequentially depositing a multi-layer thin film and the metal hard mask on the MTJ bottom electrode;
performing patterning on the metal hard mask; and
with the metal hard mask as an etching mask, etching the multi-layer thin film by an ion beam etching process, so as to obtain the magnetic tunnel junction.

14. The method according to claim 1, wherein providing the substrate comprises:
forming a bottom metal layer;
forming an etching stop layer on the bottom metal layer;
forming, on the etching stop layer, a bottom via that penetrates through the etching stop layer and is in contact with the bottom metal layer, wherein the bottom interconnection structure comprises the bottom metal layer and the bottom via; and
forming the MTJ bottom electrode on the bottom interconnection structure, wherein a second interlayer dielectric surrounds the bottom interconnection structure and the MTJ bottom electrode.

15. The method according to claim 1, wherein a surface of the first interlayer dielectric remained after etching back and the protective layer remained after etching back is lower than the surface of the metal hard mask.

16. The method according to claim 3, wherein after the in-situ plasma cleaning, dry-method photoresist removal and wet-method cleaning processes are performed, a surface of the obtained metal hard mask that is away from the top of the magnetic tunnel junction is a convex spherical contact surface.

17. The method according to claim 1, wherein a material of the MTJ bottom electrode comprises tantalum nitride, tantalum, titanium nitride, or titanium.

18. The method according to claim 1, wherein a thickness of the MTJ bottom electrode is 10-40 nm.

19. The method according to claim 1, wherein the magnetic tunnel junction is a stacked structure at least comprising a free layer, a barrier layer and a reference layer.

20. The method according to claim 1, wherein a thickness of the metal hard mask is 30-60 nm.
